(19) United States
(12) Patent Application Publication
(10) Pub. No.: US 2010/0075488 A1
(43) Pub. Date: Mar. 25, 2010

(54) CVD REACTOR WITH MULTIPLE PROCESSING LEVELS AND DUAL-AXIS MOTORIZED LIFT MECHANISM

(75) Inventors: Richard O. Collins, Santa Clara, CA (US); Nyi O. Myo, San Jose, CA (US); Kevin J. Bautista, San Jose, CA (US); John S. Webb, Sunnyvale, CA (US); Errol C. Sanchez, Tracy, CA (US); Yi-Chiau Huang, Fremont, CA (US); Kailash Kiran Patalay, Santa Clara, CA (US); Zhi Yuan Zhou, Union City, CA (US); Wilson Yu, Fremont, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/560,073

(22) Filed: Sep. 15, 2009

Related U.S. Application Data
(60) Provisional application No. 61/098,699, filed on Sep. 19, 2008.

(51) Int. Cl. H01L 21/20; C23C 16/458

(52) U.S. Cl. 438/507; 118/719; 118/730; 438/584; 257/E21.09

(57) ABSTRACT

An apparatus for processing a substrate, comprising a processing chamber and a substrate support and lift pin assembly disposed within the chamber. The substrate support and lift pin assembly are coupled to a lift mechanism that controls positioning of the substrate support and the lift pins and provides rotation for the substrate support. The lift mechanism includes at least one sensor capable of generating a signal when clearance between the substrate support and the lift pins allows rotation of the substrate support to begin. The substrate support capable of concurrent axial motion and rotation may be used in a processing chamber comprising multiple processing zones separated by edge rings. Substrates may be subjected to successive or cyclical processes by moving between the multiple processing zones.

### CROSS-REFERENCE TO RELATED APPLICATIONS

This application claims benefit of U.S. Provisional Patent Application Ser. No. 61/098,699 (APPM/12952L/FEP/EPI/PJT) filed Sep. 19, 2008.

### FIELD

Embodiments of the invention relate to deposition and etch reactions on a semiconductor substrate, such as an epitaxial deposition process or other chemical vapor deposition process. More specifically, embodiments of the invention relate to an apparatus for manipulating a substrate to perform such processes.

### BACKGROUND

Epitaxial growth of silicon and/or germanium-containing films has become increasingly important due to new applications for advanced logic and DRAM devices, among other devices. As smaller transistors are manufactured, ultra shallow source/drain junctions for sub-100 nm CMOS (complementary metal-oxide semiconductor) devices, such as silicon-containing MOSFET (metal oxide semiconductor field effect transistor) devices, are becoming more challenging to produce. Silicon based materials may be used in device creation for MOSFET devices. For example, in a PMOS application, the film in a recessed area of the transistor is usually silicon-germanium, and for a NMOS application, the film in the recessed area may be SiC. Silicon-germanium is advantageously used to implant more boron than silicon alone to reduce junction resistivity, which improves device performance, for example, the silicon-germanium interface with the silicide layer at the substrate surface has a lower Schottky barrier than the silicon interface with silicon-germanium.

Selective silicon-epitaxial (Si-epitaxial) deposition and silicon-germanium-epitaxial deposition permits growth of epilayers on silicon (Si) moats with no growth on dielectric areas. Selective epitaxy can be used in semiconductor devices, such as within source/drains, source/drain extensions, contact plugs, and base layer deposition of bipolar devices. Additionally, selective epitaxy permits near complete dopant activation with in-situ doping, so that the post annealing process may be omitted. Therefore, junction depth can be defined accurately by silicon etching and selective epitaxy. Improved junction depth also produces compressive stress. One example of the use of silicon containing materials in device creation is for MOSFET devices.

As in most processes, efficient and non-destructive manipulation of substrates in epitaxial processes is desired. For example, in many epitaxial processes, a substrate is rotated to ensure uniform deposition. Additionally, substrates are generally raised and lowered in preparation for processing, and also thereafter. Because handling substrates can generate particles inside processing chambers, it is desired that such handling be relatively gentle. Control of substrate positioning during processing may also impact the quality of deposited films. Thus, there is a need for an apparatus capable of depositing an epitaxial film on a substrate while positioning the substrate most desirably and handling the substrate without generating particles.

### SUMMARY

Embodiments of the invention generally provide an apparatus for processing a substrate, comprising a processing chamber comprising a lid, a floor, and a wall, a substrate support disposed within the processing chamber and having a lift shaft that penetrates the floor, and a lift mechanism configured to translate the substrate vertically within the chamber, operate lift pins to lift the substrate above the substrate support, and rotate the substrate while translating it within the chamber. Some embodiments feature a magnetically actuated rotor attached to the lift shaft, with a magnetic actuator coupled to a motor to provide rotation.

Other embodiments provide a process chamber for processing a semiconductor substrate, comprising a sidewall, top, and bottom defining an internal volume of the process chamber, a plurality of edge rings disposed along the sidewall, each edge ring defining a boundary of at least one processing zone in the internal volume of the process chamber, a substrate support disposed in the internal volume of the chamber and configured to rotate about a central axis of the substrate support while moving in a direction parallel to the central axis, and a gas conduit coupled to each processing zone of the processing chamber.

Other embodiments provide a method of processing a semiconductor substrate, comprising positioning the substrate on a substrate support in the processing chamber, rotating the substrate on the substrate support, and moving the substrate along an axis of rotation while rotating the substrate.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of one embodiment of a deposition chamber.

FIG. 2 is a cross-sectional detail view of a portion of the deposition chamber shown in FIG. 1.

FIG. 3 is a schematic cross-sectional view of another embodiment of a deposition chamber.

FIG. 4 is a flow diagram summarizing a method according to another embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

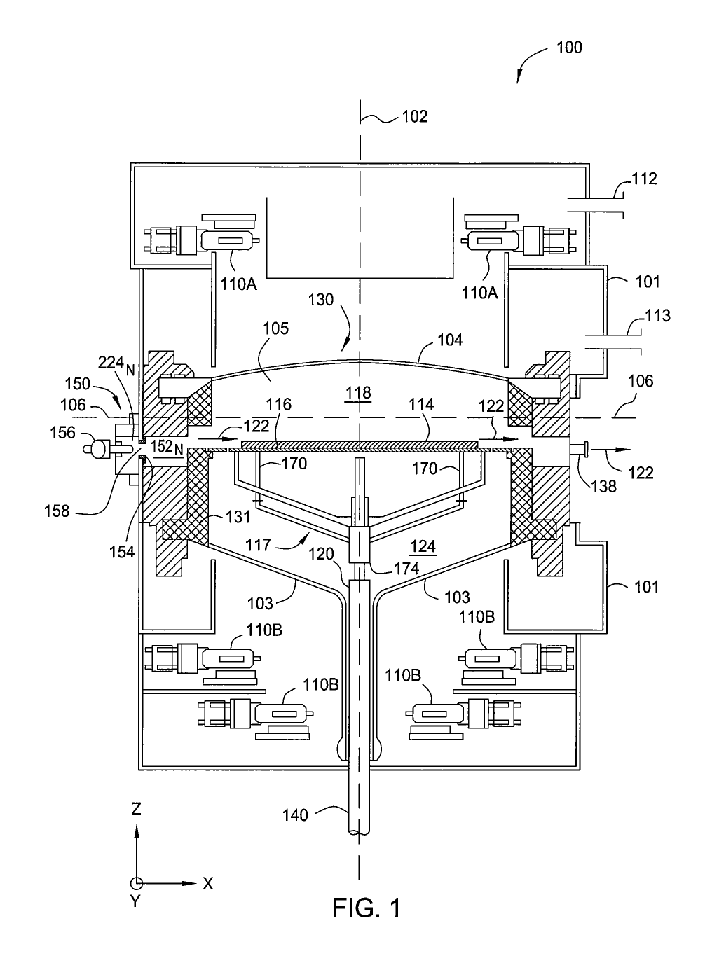

Embodiments of the invention generally provide an apparatus for depositing a film on a substrate. FIG. 1 is a schematic cross-sectional view of a deposition chamber 100 configured for epitaxial deposition, which may be part of a CENTURA® integrated processing system available from Applied Materials, Inc., of Santa Clara, Calif. The deposition chamber 100 includes housing structure 101 made of a process resistant material, such as aluminum or stainless steel, for example 316L stainless steel. The housing structure 101 encloses various functioning elements of the process chamber 100, such as a quartz chamber 130, which includes an upper chamber 105, and a lower chamber 124, in which a processing volume 118 is contained. Reactive species are provided to the quartz chamber 130 by a gas distribution assembly 150, and processing byproducts are removed from processing volume 118 by an outlet 138, which is typically in communication with a vacuum source (not shown).

A substrate support 117 is adapted to receive a substrate 114 that is transferred to the processing volume 118 on a surface 116 of the substrate support 117. The substrate support 117 may be made of a ceramic material or a graphite material coated with a silicon material, such as silicon carbide, or other process resistant material. Reactive species from precursor reactant materials are applied to the exposed surface of the substrate 114, and byproducts may be subsequently removed from the surface of the substrate 114. Heating of the substrate 114 and/or the processing volume 118 may be provided by radiation sources, such as upper lamp modules 110A and lower lamp modules 110B. The substrate support 117 may rotate about a central axis 102 of the substrate support while moving in a direction parallel to the central axis 102 by displacement of support shaft 140. Lift pins 170 are provided that penetrate the surface 116 of the substrate support 117 and lift the substrate 114 above the substrate support 117 for transportation into and out of the processing chamber. The lift pins 170 are coupled to the support shaft 140 by a lift pin collar 174.

In one embodiment, the upper lamp modules 110A and lower lamp modules 110B are infrared (IR) lamps. Non-thermal energy or radiation from lamp modules 110A and 110B travels through upper quartz window 104 of upper quartz chamber 105, and through the lower quartz portion 103 of lower quartz chamber 124. Cooling gases for upper quartz chamber 105, if needed, enter through an inlet 112 and exit through an outlet 113. Precursor reactant materials, as well as diluent, purge and vent gases for the chamber 100, enter through gas distribution assembly 150 and exit through outlet 138.

The low wavelength radiation in the processing volume 118, which is used to energize reactive species and assist in adsorption of reactants and desorption of process byproducts from the surface 116 of substrate 114, typically ranges from about 0.8 μm to about 1.2 μm, for example, between about 0.95 μm to about 1.05 μm, with combinations of various wavelengths being provided, depending, for example, on the composition of the film which is being epitaxially grown. In another embodiment, the lamp modules 110A and 110B may be ultraviolet (UV) light sources. In one embodiment, the UV light source, is an excimer lamp. In another embodiment, UV light sources may be used in combination with IR light sources in one or both of the upper quartz chamber 105 and lower quartz chamber 124. An example of UV radiation sources used in combination with IR radiation sources can be found in U.S. patent application Ser. No. 10/866,471, filed Jun. 10, 2004, which published on Dec. 15, 2005, as United States patent publication No. 2005/0277272, which is incorporated by reference in its entirety.

The component gases enter the processing volume 118 via gas distribution assembly 150 through port 158, which may have a portal liner 154, and through passage 152N. The portal liner 154 may be a nozzle in some embodiments. The gas distribution assembly 150 includes a tubular heating element 156, disposed in a conduit 224N, that heats the processes gases to a desired temperature before they enter the processing chamber. Gas flows from the gas distribution assembly 150 and exits through port 138 as shown generally at 122. Combinations of component gases, which are used to clean/passivate a substrate surface, or to form the silicon and/or germanium-containing film that is being epitaxially grown, are typically mixed prior to entry into the processing volume. The overall pressure in the processing volume 118 may be adjusted by a valve (not shown) on the outlet port 138. At least a portion of the interior surface of the processing volume 118 is covered by a liner 131. In one embodiment, the liner 131 comprises a quartz material that is opaque. In this manner, the chamber wall is insulated from the heat in the processing volume 118.

The temperature of surfaces in the processing volume 118 may be controlled within a temperature range of about 200° C. to about 600° C., or greater, by the flow of a cooling gas, which enters through a port 112 and exits through port 113, in combination with radiation from upper lamp modules 110A positioned above upper quartz window 104. The temperature in the lower quartz chamber 124 may be controlled within a temperature range of about 200° C. to about 600° C. or greater, by adjusting the speed of a blower unit which is not shown, and by radiation from the lower lamp modules 1108 disposed below lower quartz chamber 124. The pressure in the processing volume 118 may be between about 0.1 Torr to about 600 Torr, such as between about 5 Torr to about 30 Torr.

The temperature on a surface of the substrate 114 may be controlled by power adjustment to the lower lamp modules 1108 in lower quartz chamber 124, or by power adjustment to both the upper lamp modules 110A overlying upper quartz chamber 105, and the lower lamp modules 1108 in lower quartz chamber 124. The power density in the processing volume 118 may be between about 40 W/cm² to about 400 W/cm², such as about 80 W/cm² to about 120 W/cm².

In one aspect, the gas distribution assembly 150 is disposed normal to, or in a radial direction 106 relative to, the longitudinal axis 102 of the chamber 100 or substrate 114. In this orientation, the gas distribution assembly 150 is adapted to flow process gases in a radial direction 106 across, or parallel to, a surface of the substrate 114. In one application, the process gases are preheated at the point of introduction to the chamber 100 to initiate preheating of the gases prior to introduction to the processing volume 118, and/or to break specific bonds in the gases. In this manner, surface reaction kinetics may be modified independently from the thermal temperature of the substrate 114.

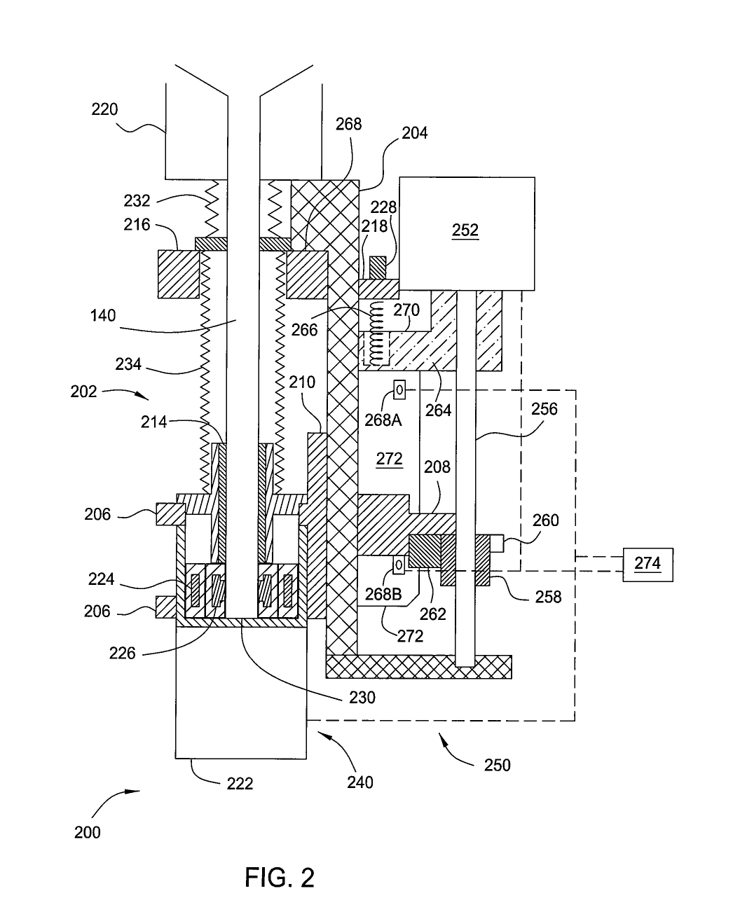

FIG. 2 is a cross-sectional detail view of a portion of the deposition chamber of FIG. 1. FIG. 2 illustrates a support mechanism 200 for a substrate support used for processing a substrate in a processing chamber. The support mechanism 200 comprises a support shaft assembly 202 and a lift assembly 250. The support shaft assembly 202 is coupled to the lift assembly 250 by a support bracket 204. The support bracket 204 has openings (not shown) to allow components of the support shaft assembly 202 to couple to components of the lift assembly 250.

The lift assembly 250 comprises a lift motor 252 coupled to a lift actuator 256. The lift actuator 256 may be a screw-type actuator rotatably coupled to the lift motor 252 in some embodiments. The lift actuator 256 is coupled to a lift coupling 258. The lift coupling 258 couples to components of the support shaft assembly 202, as described in further detail below. In embodiments wherein the lift actuator 256 is a screw-type actuator, the lift coupling 258 may be a threaded collar. In embodiments featuring a threaded lift collar and screw-type lift actuator, the lift collar rides along a longitudinal direction of the lift actuator by virtue of threads on the lift actuator that mate with threads on the lift collar. As the motor turns the lift actuator, threads on the lift actuator mated to threads on the lift collar force the lift collar to move along the lift actuator in a longitudinal direction. In alternate embodiments, the lift coupling 258 may be a glide coupling that mates with a rail or an unthreaded collar that slides along a rod, either of which may be actuated by a linear actuator coupled to the lift motor 252.

In embodiments wherein the lift actuator 256 rotates, the lift coupling 258 may be prevented from rotating by a compression bracket 260, which is coupled to a compression seat 262 by fasteners (not shown). Application of the compression bracket 260 and compression seat 262 to the lift coupling 258 results in a frictional force on the lift coupling 258 that prevents rotation. In another embodiment, the lift coupling 258 may be prevented from rotating by providing a guide rod substantially parallel to the lift actuator 256 and passing through a portion of the lift coupling 258. In such an embodiment, the lift coupling 258 may ride along the guide rod, which would prevent rotation of the lift coupling 258 with the lift actuator 256. In other alternate embodiments, a threaded lift collar may be prevented from rotating in other ways, such as by providing a ridge or tab on an outside surface of the lift coupling 258 that can mate with a groove in a member, such as a rail, fastened to the motor 252.

The support shaft assembly 202 comprises the support shaft 140, a rotation assembly 240, a chamber coupling 220, an upper bellows 232, and a lower bellows 234. The support shaft 140 is coupled with the surface 116 of the substrate support 117 at a first end 120 of the support shaft 140 (FIG. 1) to effect rotational and translational movement of the surface 116, and with the rotation assembly 240 at a second end 230 of the support shaft 140. The rotation assembly 240 comprises a support cup 214 coupled to the support shaft 140 and to a rotational motor 222. The support cup 214 comprises a magnetic actuator 224 coupled to the rotational motor 222, and magnetically coupled to a rotor 226. The rotor 226, which may be a magnetic rotor, is attached to the support shaft 140, and transmits rotational motion from the rotational motor 222 to the support shaft 140.

The rotation assembly 240 is coupled with the lift assembly 250 by a first lift member 206. The first lift member 206 comprises a first extension 208 that couples the rotation assembly 240 to the lift coupling 258. The first extension 208 extends through the support bracket 204 and couples to the lift coupling 258, or the compression seat 262, or both. As the lift coupling 258 moves, the first lift member 206 moves the support shaft assembly 202 accordingly. The first lift member 206 may also comprise a support plate 210 in some embodiments. The support plate 210 generally constrains motion of the support shaft assembly 202 to one dimension by ridges or extensions (not shown) that mate with channels or openings in the support bracket 204.

The support shaft assembly 202 further comprises a second lift member 216. The second lift member 216 is coupled to the lift assembly 250 by a second extension 218 and a resilient member 266. The second extension 218 also couples the support mechanism 200 to a lift pin assembly, such as the lift pin collar 174 and lift pins 170 of FIG. 1, by a lift pin actuator 228, such that the lift pins 170 travel with the second lift member 216. The second extension 218 is resiliently mated to an unmoving portion of the lift assembly 250, such as a motor mount 264, which may be attached to the support bracket 204, by the resilient member 266. In one embodiment, the resilient member 266 is a spring, but any member that provides restorative force when deformed may be used. For example, in some embodiments the resilient member 266 may be a polymeric pad or cushion.

The second lift member 216 moves with the support shaft assembly 202 by virtue of the lower bellows 234. Movement of the second lift member 216 is constrained, however, by features of the lift assembly 250. As the second lift member 216 moves toward the processing chamber, a restorative force develops in the resilient member 266 tending to urge the second lift member 216 away from the processing chamber. Additionally, an upper stop 268 is positioned at the desired location with respect to any feature fastened unmovably to the lift assembly 250, such as the support bracket 204 or the motor mount 264. When the second lift member 216 impinges the upper stop 268, movement of the second lift member 216 toward the processing chamber stops.

Features of the lift assembly 250 also constrain withdrawal of the second lift member 216. As the second lift member 216 moves away from the processing chamber, a restorative force develops in the resilient member 266 tending to urge the second lift member toward the processing chamber. Additionally, a lower stop 270 is also provided to constrain withdrawal of the second lift member 216. In the embodiment of FIG. 2, the motor mount 264 provides the lower stop 270 for the second lift member 216 by virtue of the second extension 218. When the second extension 218 impinges the lower stop 270, movement of the second coupling bracket away from the processing chamber stops. Although the embodiment of FIG. 2 features use of the motor mount 264 as a lower stop, other embodiments may feature another member provided as a lower stop. Any such member may be fastened to the lift assembly 250, such as by fastening to the support bracket 204, the motor mount 264, or the motor 252.

As the support shaft 140 is lowered by the lift motor 252, the second lift member 216 initially travels with the support shaft 140 by virtue of the lower bellows 234, thus lowering the lift pins 170 (FIG. 1) along with the substrate support 117. Restorative force develops in the resilient member 266 as the second extension 218 approaches the lower stop 270. When the second extension 218 impinges the lower stop 270, the second lift member 216 stops moving, and the lift pins 170 (FIG. 1) also stop moving. As the support shaft 140 continues moving, the substrate support 117 (FIG. 1) continues lower, while the lift pins 170 (FIG. 1) remain stationary. The lift pins (170) thus protrude above the surface 116 of the substrate support 114, lifting the substrate 114 above the substrate support 117.

When the support shaft 140 is raised by the lift motor 252, the restorative force of the resilient member 266, tension in the lower bellows 234 initially overcomes the restorative force in the resilient member 266, holding the second extension 218 against the lower stop 270 and keeping the lift pins 170 (FIG. 1) in place. The substrate support 117 thus approaches the substrate 114 held above the substrate support 117 by the lift pins 170. When the support shaft 140 is raised to a point that the restorative force of the resilient member 266 overcomes the tension in the lower bellows 234, the second lift member 216 begins moving with the support shaft 140, and the lift pins 170 also begin moving with the substrate support 117. As the resilient member 266 reaches an equilibrium position, the lift pins 170 retract such that the substrate 114 is deposited on the substrate support 117.

When the second extension 218 reaches the upper stop 268, the second lift member 216 and the lift pins 170 (FIG. 1) stop moving. The support shaft 140 and the substrate support 117 continue moving the substrate 114 into a processing position. Thus, the distance between the lift pins 170 and the substrate support 117 grows. This distance enables the substrate support 117 to be rotated without endangering the lift pins 170.

Because the support shaft 140 travels into the processing chamber, and the processing chamber is generally maintained at low pressure, the support shaft 140 is generally maintained in a low pressure environment to avoid contamination of the reaction zone inside the processing chamber. The upper bellows 232 provides a low-pressure enclosure between the second lift member 216 and the chamber coupling 220. The lower bellows 234 provides a low-pressure enclosure between the second lift member 216 and the first lift member 206. In this way, the support shaft 140 may be housed in an environment maintained at the same pressure as the processing chamber.

A sensor plate 272 may coupled to the lift assembly 250, for example by fastening to the support bracket 204. The sensor plate 272 provides a location for mounting sensors that may be used to control operation of the lift mechanism. The embodiment of FIG. 2 features two sensors 268A and 268B. The sensors 268A and 268B may be any type of sensor capable of detecting the proximity or passage of the support shaft assembly 202 with respect to the lift assembly 250, such as opto-electronic switches or pressure switches. The sensor 268B may be a homing sensor that switches off the lift motor 252 when the support shaft assembly 202 reaches a homing position. The sensor 268A may be coupled to the rotational motor 222, providing an interlock capability that enables rotation of the lift shaft when the lift shaft assembly passes the sensor 268A. The sensor 268A may be positioned to indicate a position of the support shaft 140 that establishes a minimum clearance between the substrate support 117 and the lift pins 170. The sensors 268A/B may also be coupled to a controller 274 that energizes and de-energizes the rotational motor 222 in response to a signal from the sensor 268A, and energizes and de-energizes the lift motor 252 in response to a signal from the sensor 268B.

It should be noted that the sensor 268A, functioning as a rotation interlock sensor, enables rotation of the substrate 114 (FIG. 1) while the substrate support 117 moves in a direction parallel to the central axis 102. This capability reduces the overall processing time in the chamber by establishing rotation while moving the substrate 114 into processing position. In addition, the lift mechanism 200 of FIG. 2 enables fine control of the substrate support 117 by virtue of the support shaft 140, so that the substrate support 117 may be raised toward the substrate 114 at maximum velocity and decelerated immediately before contacting the substrate 114 to provide a low-force contact between the substrate support 117 and the substrate 114. The low-force contact minimizes physical disruption of the substrate and particle generation thereby. Finally, the independent control of rotation and translation of the substrate allows for a larger process window. For example, the substrate may be positioned at any point with respect to the passage 152_{N} to control the deposition reaction. In one embodiment, the substrate may be rotatably positioned between about 0.6 inches below the passage 152_{N} and about 0.2 inches above the passage 152_{N}. In other embodiments, the position of the substrate may be changed during the reaction without stopping rotation. Thus, a position profile may be executed during the reaction to control progress of the deposition and engineer properties of the deposited films.

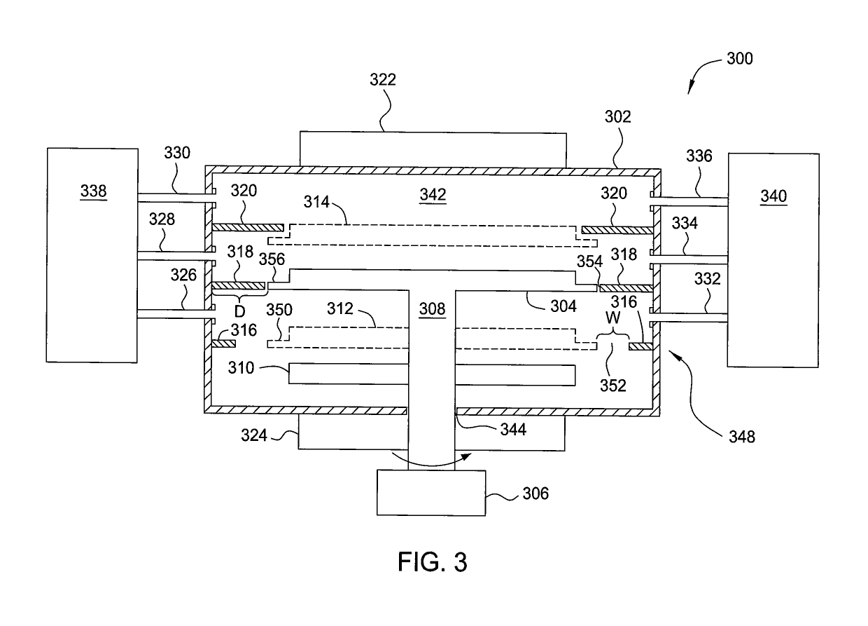

The support mechanism 200, with concurrent axial and rotational movement, also enables processing a substrate at different levels in the processing chamber, or in different processing zones of the processing chamber. FIG. 3 is a schematic cross-sectional view of another embodiment of a deposition chamber 300. The chamber 300 comprises an enclosure 302 that defines an internal volume 342. A substrate support 304 is disposed in the internal volume 342 of the chamber 300, and is coupled to an actuator 306 by a shaft 308 that extends through an opening 344 in the enclosure 302. The actuator 306 moves the substrate support to different processing positions 312 and 314 within the internal volume 342 of the chamber 300 while rotating. Energy sources 322 and 324, each of which may be a bank of heat lamps, may be used separately or together to add energy to the internal volume 342 of the chamber 300.

The chamber 300 further comprises one or more edge rings 348 that define processing zones within the internal volume 342. The edge rings 348 may comprise up to five edge rings, for example between one and five edge rings. In some embodiments, a chamber may have a plurality of edge rings. In the embodiment of FIG. 3, three edge rings 316, 318, and 320, are shown.

Each edge ring defines a boundary of at least one processing zone, as well as an opening in which the substrate support 304 is positioned to define a lower of the processing zone. For example, a first processing zone is defined by a first edge ring and a second edge ring above the first edge ring. The lower boundary of the first processing zone is defined by the first edge ring and the upper boundary of the first processing zone is defined by the second edge ring, which may also define the lower boundary of a second processing zone above the first processing zone. When the substrate support is positioned proximate to the first edge ring, in an opening defined by the first edge ring, it provides a floor for the first processing zone while a substrate is being processed therein.

The plurality of edge rings 348 comprises one edge ring 320 that extends over a shoulder 350 of the substrate support 304, which will usually be the uppermost edge ring of the chamber. The other edge rings, for example the edge rings 316 and 318 of FIG. 3, each has an opening through which the substrate support 304 may pass to access the various processing zones defined by the edge rings.

As the substrate support is positioned proximate to the edge rings 316 and 318, first and second gaps, 352 and 354 respectively, are defined by inner radii of the edge rings 316 and 318 and an edge portion 356 of the substrate support 304. For example the first edge ring 316 defines the gap 352 between the inner radius of the first edge ring 316 and the edge portion 356 of the substrate support 304 when the substrate support is positioned proximate the first edge ring 316, and the second edge ring 318 defines the gap 354 between the inner radius of the second edge ring 318 and the edge portion 356 of the substrate support 304 when the substrate support is positioned proximate the second edge ring 316.

The gaps 352 and 354, or all such gaps between edge rings and the substrate support 304 in embodiments featuring more or less than three edge rings, may vary in width depending on the geometry of the chamber and the desired processing characteristics. In most embodiments, the gaps will each have a width “W” between about 0.5% and about 75% of the distance “D” between the edge portion 356 of the substrate support 304 and the chamber enclosure 302. In a chamber adapted to process 300 mm substrates, the gaps may each have a width between about 1 mm and about 100 mm. In some embodiments, the gaps may all have the same width W, while in other embodiments, such as that shown in FIG. 3, the gaps may have different widths W. For example, as shown in FIG. 3, the gap 354 may have a width W that is less than the width W of the gap 352.

Gas is provided to the various processing zones defined by the edge rings through a plurality of gas conduits, each of which is coupled to a processing zone. In FIG. 3, three gas conduits 326, 328, and 330 provide gas to the three processing zones defined by the edge rings 316, 318, and 320, respectively. A single gas source 338 is shown providing gas to the three gas conduits 326, 328, and 330, but multiple gas sources may also be used to feed any number of conduits in any conceivable configuration. Gas is exhausted from the chamber, in turn, through a plurality of exhaust conduits, each of which is coupled to a processing zone, similar to the gas conduits. In FIG. 3, three exhaust conduits 332, 334, and 336, exhaust gas to the exhaust system 340, which may represent any number of exhaust systems coupled to any number of conduits in any conceivable configuration.

Substrates are provided to, and removed from, the chamber through opening 310 below the lowermost processing zone. As discussed above in connection with FIG. 2, the lift mechanism stops the rotation mechanism by operation of proximity sensors or switches, and lift pins deploy as the substrate support 304 approaches a loading or unloading position proximate the opening 310.

In operation, the substrate support is positioned proximate to one of the edge rings, such as the edge ring 318. Gas is provided through the conduit serving the processing zone defined by the edge ring 318 and the substrate support 304, which in the FIG. 3 embodiment is gas conduit 328. The gas flows across the substrate disposed on the substrate support 304 to perform a deposition process, and excess gas flows out through the exhaust conduit 334 to the exhaust system 340. Gas may also be provided through processing zones above and/or below the active processing zone to prevent reactive gases from escaping the active processing zone through adjacent zones. For example, during processing in the zone with lower boundary defined by edge ring 318, a non-reactive or purge gas may be provided through gas conduits 330 and 326 to minimize reactive gas concentration in zones above edge ring 320 and below edge ring 318.

After processing in a first processing zone, the substrate support 304 is moved to a second processing zone by moving along an axis of the substrate support 304. Rotation of the substrate support is maintained during movement between processing zones to minimize non-productive time. Processing conditions in the second processing zone may be established prior to moving the substrate support into position so that processing commences immediately.

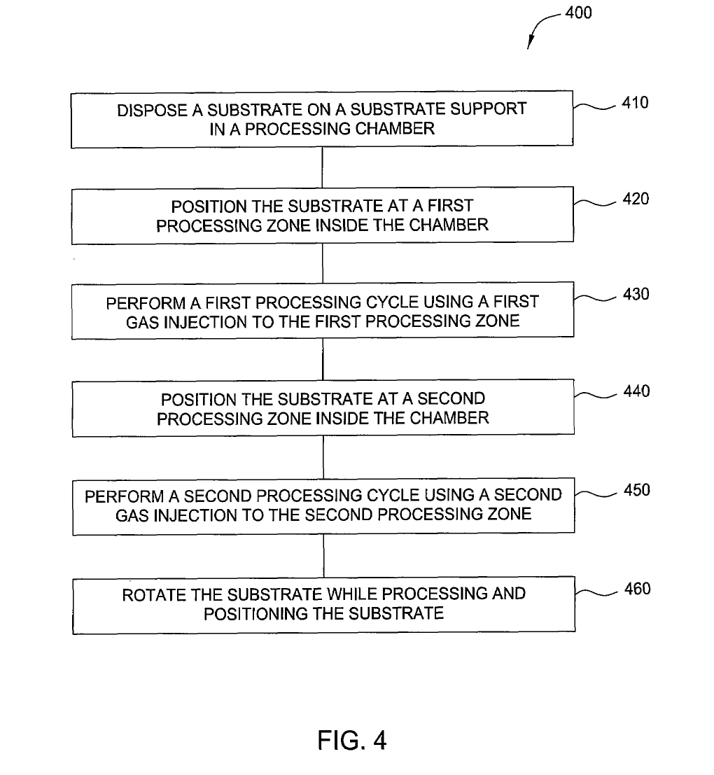

FIG. 4 is a flow diagram summarizing a method 400 according to another embodiment. The method 400 is useful for performing cyclical processes on semiconductor substrates, such as ALD processes, CVD processes, epitaxy processes, and etch processes.

A substrate is disposed on a substrate support in a processing chamber at 410. A processing chamber such as the chamber 300 of FIG. 3 may be used to practice the method 400.

The substrate is positioned at a first processing zone inside the process chamber at 420. The substrate support is moved from a loading or unloading position at 410 to the first processing zone. In some embodiments, the first processing zone is defined by a first divider, which may be a first plurality of dividers, that define the first processing zone. As the substrate support moves to a position proximate the first divider, the substrate disposed on the substrate support enters the first processing zone.

At 430, a first processing cycle is performed on the substrate in the first processing zone. A first gas is provided to the first processing zone, and energy may be added using the substrate support or another energy source positioned inside or outside the processing chamber. In one embodiment, a heat source may be positioned above or below the chamber, or both, to heat substrates during processing. In one embodiment, processing conditions such as substrate temperature and pressure above the substrate are achieved at the time the substrate reaches the first processing zone. In other embodiments, the desired processing conditions may be established in the first processing zone before positioning the substrate support. In either embodiment, processing may begin immediately when the substrate enters the first processing zone.

At 440, the substrate is positioned at a second processing zone by moving the substrate support. Similar to the first processing zone, the second processing zone may be defined by a second divider to minimize cross flow of gases from one processing zone to another. A gas curtain may also be provided between the processing zones. The gas curtain may also be useful for performing a cooling operation between two deposition or etch operations. The gas curtain may also be useful for purging reactants from the substrate surface between operations.

At 450, a second processing cycle is performed on the substrate in the second processing zone. A second gas is provided to the second processing zone. As with the first processing zone, energy may be added to the second processing zone using the same energy source or a different energy source. For example, if the first processing zone is proximate a first energy source, and the second processing zone proximate a second energy source, the first energy source may be used during the first processing cycle and the second energy source during the second processing cycle.

At 460, the substrate is rotated during processing, and the rotation is maintained while processing and positioning the substrate. For process cycles wherein rotation is not advantageous, rotation may be stopped and then restarted for subsequent process cycles in which rotation is desired. Rotation is generally maintained while moving the substrate between processing zones such that processing may start immediately when the substrate enters the next processing zone. No time is spent waiting for rotation to achieve the desired RPM.

In an exemplary embodiment, a chamber having three processing zones similar to the chamber 300 of FIG. 3 may be used to perform an ALD process efficiently. Processing conditions for depositing a first precursor on a substrate may be established in a first processing zone, for example the lowest processing zone, and conditions for depositing a second precursor to react with the first precursor may be established in the second processing zone. Performing the ALD deposition then amounts to moving the substrate between the two processing zones in a prescribed manner. A gas curtain may be provided between the processing zones to remove any excess reactants from the substrate as it moves between the zones. After the ALD process is performed in the first and second processing zones, a cleaning operation may be performed in the third processing zone, if desired.

In another exemplary embodiment, a sequential deposition and etch process may be performed in such a chamber by establishing process conditions for the two processes in adjacent processing zones and moving the substrate between them in a prescribed manner. It should be noted that a processing chamber having three or more processing zones may be used to perform long, complex processes involving many more than three operations by adjusting processing conditions in idle processing zones. For example, after performing three operations in three different processing zones, processing conditions in the idle processing zones may be changed to perform a fourth, fifth, or further operations on the substrate.

In some embodiments, the processing conditions established in a processing zone may involve activated precursors. In one embodiment, remotely activated precursors may be provided to one or more processing zones. Remotely activated precursors may be provided to one processing zone while non-activated, or even inert, precursors are provided to an adjacent processing zone. In one embodiment, a processing zone, for example the uppermost or lowermost processing zone, may be positioned adjacent to an inductive source for producing an inductively coupled plasma in the uppermost or lowermost processing zone. The inductive source may be operated in a way that couples energy into the desired processing zone at a power level selected to drive a reaction in the processing zone while declining to a level below that required to drive a reaction in an adjacent processing zone. Such conditions may be useful for performing a plasma deposition, plasma etch, or plasma cleaning operation as part of a larger sequence of operations. If necessary, an electrical bias may be coupled to the substrate support, if desired for certain operations in certain processing zones.

While the foregoing is directed to embodiments of the invention, other and further embodiments of the invention may be devised without departing from the basic scope thereof.

What is claimed is:

1. A process chamber for processing a semiconductor substrate, comprising:
an enclosure defining an internal volume of the process chamber;
one or more edge rings disposed along the enclosure, each edge ring defining a boundary of at least one processing zone in the internal volume of the process chamber;
a substrate support disposed in the internal volume of the chamber and configured to rotate about a central axis of the substrate support while moving in a direction parallel to the central axis; and
a gas conduit coupled to each processing zone of the processing chamber.

2. The process chamber of claim 1, wherein each edge ring defines a boundary of a processing zone above the edge ring and an opening in which the substrate support is positioned to form a floor for the processing zone.

3. The process chamber of claim 1, wherein the one or more edge rings comprises between three and five edge rings.

4. The process chamber of claim 1, wherein the substrate support comprises a shoulder and at least one edge ring extends over the shoulder.

5. The process chamber of claim 4, wherein the one or more edge rings comprises an edge ring that extends over the shoulder of the substrate support, and the edge ring that extends over the shoulder of the substrate support is the uppermost edge ring in the process chamber.

6. The process chamber of claim 1, wherein the one or more edge rings comprises a first edge ring and a second edge ring, the first edge ring defining a first gap between an inner radius of the first edge ring and an edge portion of the substrate support when the substrate support is positioned proximate to the first edge ring, the second edge ring defining a second gap between an inner radius of the second edge ring and an edge portion of the substrate support when the substrate support is positioned proximate to the second edge ring, and the first and second gaps have different widths.

7. A method of processing a semiconductor substrate, comprising:
positioning the substrate on a substrate support in the processing chamber;
rotating the substrate on the substrate support; and
moving the substrate along an axis of rotation while rotating the substrate.

8. The method of claim 7, further comprising providing a process gas to the processing chamber while rotating the substrate.

9. The method of claim 7, further comprising defining a plurality of processing zones by positioning dividers in the processing chamber through which the substrate support can pass.

10. The method of claim 9, further comprising:
processing the substrate in a first processing zone;
maintaining rotation of the substrate;
moving the substrate along the axis of rotation to a second processing zone; and
processing the substrate in the second processing zone.

11. The method of claim 10, wherein processing the substrate in the first processing zone comprises providing a first processing condition in the first processing zone, and processing the substrate in the second processing zone comprises providing a second processing condition in the second processing zone.

12. The method of claim 11, wherein processing the substrate in the first processing zone further comprises providing a non-reactive gas to the second processing zone.

13. A process chamber, comprising:
a substrate support disposed in the process chamber, the substrate support comprising:
a substrate support surface coupled with a first end of a support shaft that extends through a floor of the process chamber and coupled with a rotation assembly at a second end of the support shaft;
a lift assembly comprising a first lift member coupled to the rotation assembly and to a lift actuator, and a second lift member coupled to the support shaft and to a lift pin actuator.

14. The process chamber of claim 13, wherein the lift assembly further comprises a lift motor, a stop fastened to the lift motor, and a resilient member coupling the stop to the first lift member.

15. The process chamber of claim 13, wherein the rotation assembly comprises a support cup disposed about the second end of the support shaft and coupled to the lift assembly by the first lift member.

16. The process chamber of claim 15, wherein the support cup comprises a plurality of magnetic inserts that couple magnetically to a magnetic rotor attached to the support shaft.

17. The process chamber of claim 13, wherein the lift assembly further comprises a sensor electrically coupled to the rotation assembly and activated by the position of the first lift member.

18. The process chamber of claim 13, wherein the second lift member travels along the support shaft between the stop and a limit member attached to the lift assembly.

19. The process chamber of claim 13, wherein the lift actuator comprises a screw and a threaded collar coupled to the second lift member.

20. The process chamber of claim 16, wherein the support cup is coupled to a rotation motor.
